(19) United States
(12) Patent Application Publication
(10) Pub. No.: US 2021/0359285 A1
(43) Pub. Date: Nov. 18, 2021

(54) DISPLAY PANEL AND MANUFACTURING METHOD THEREOF

(71) Applicant: WUHAN CHINA STAR OPTOELECTRONICS SEMICONDUCTOR DISPLAY TECHNOLOGY CO., LTD., Wuhan (CN)

(72) Inventor: Wanliang ZHOU, Wuhan, Hubei (CN)

(21) Appl. No.: 16/967,138

(22) PCT Filed: Jun. 2, 2020
(86) PCT No.: PCT/CN2020/093953

§ 371 Date: Aug. 4, 2020

(30) Foreign Application Priority Data
May 18, 2020 (CN) 202010420890.7

(51) Int. Cl. H01L 51/56; H01L 27/32; H01L 51/00; H01L 51/52

(52) U.S. Cl. CPC H01L 51/56; H01L 27/3262; H01L 27/3272; H01L 51/0023; H01L 27/1225; H01L 51/5234; H01L 2227/323; H01L 2251/5323; H01L 51/5218

(57) ABSTRACT

A display panel and a manufacturing method thereof are provided. The display panel manufactured by the method includes bottom emitting organic light-emitting diode (OLED) units and top emitting OLED units. The bottom emitting OLED units include a first type of anode and a first type of cathode, and the top emitting OLED units include a second type of anode and a second type of cathode. The first type of anode has light transmittance, the second type of anode has reflectivity, the first type of cathode has reflectivity, and the second type of cathode has light transmittance.

### FIELD OF INVENTION

The present disclosure relates to the field of display technologies, and more particularly, to a display panel and a manufacturing method thereof.

### BACKGROUND OF INVENTION

In recent years, active matrix organic light-emitting diode (AMOLED) displays have advantages of wide color gamut, high contrast, self-illumination, lightness, thinness, and foldability, thereby having broad application prospects in fields such as TFT displays. According to conventional dual-screen AMOLED display technologies, a dual-screen display device is usually composed of two single AMOLED display devices, wherein the single display devices need to be respectively encapsulated and then combined to bond two light-emitting devices together. Therefore, both costs and processes thereof are double that of one single display device, and such kind of dual-sided display technologies only relate to a general assembly and have no advantages. In addition to causing a burden on the costs, requirements of current electronic products for lightness, thinness, and smallness are lost.

Therefore, the current dual-sided display panels have problems of manufacturing costs being too high and display devices being not light and thin enough.

Technical problem: an embodiment of the present disclosure provides a display panel and a manufacturing method thereof, which can effectively relieve the problems of manufacturing costs being too high and display devices being not light and thin enough existing in the dual-sided display panels in current technology.

### SUMMARY OF INVENTION

In a first aspect, an embodiment of the present disclosure provides a manufacturing method of a display panel. The manufacturing method includes following steps:

providing a substrate and forming a driving circuit layer on the substrate;

forming a first type of anode and a second type of anode on the driving circuit layer, wherein a material of the first type of anode is a transparent material, a material of the second type of anode is a non-transparent material, and the first type of anode is disposed adjacent to the second type of anode;

forming a light-emitting layer on the first type of anode and the second type of anode; and

forming a first type of cathode and a second type of cathode on the light-emitting layer, wherein a material of the first type of cathode is a non-transparent material, a material of the second type of cathode is a transparent material, the first type of cathode corresponds to the first type of anode, and the second type of cathode corresponds to the second type of anode.

In the manufacturing method provided by the present disclosure, the step of providing the substrate and forming the driving circuit layer on the substrate comprises:

forming a light shielding layer, a buffer layer, and an active layer on the substrate in a stack;

depositing a first metal layer on the active layer and patterning the first metal layer to form a gate electrode;

patterning to form a dielectric layer on the gate electrode, wherein the dielectric layer is provided with through-holes on the active layer; and

patterning to form a source electrode and a drain electrode on the through-holes.

In the manufacturing method provided by the present disclosure, the step of forming the first type of anode and the second type of anode on the driving circuit layer, wherein the material of the first type of anode is a transparent material, the material of the second type of anode is a non-transparent material, and the first type of anode is disposed adjacent to the second type of anode, comprises:

forming the first type of anode and the second type of anode on the driving circuit layer respectively by masks in two vacuum evaporation processes.

In the manufacturing method provided by the present disclosure, the step of forming the first type of anode and the second type of anode on the driving circuit layer, wherein the material of the first type of anode is a transparent material, the material of the second type of anode is a non-transparent material, and the first type of anode is disposed adjacent to the second type of anode, comprises:

forming the first type of anode and the second type of anode on the driving circuit layer simultaneously by a graytone mask or a halftone mask in a same vacuum evaporation process.

In the manufacturing method provided by the present disclosure, the step of forming the first type of cathode and the second type of cathode on the light-emitting layer, wherein the material of the first type of cathode is a non-transparent material, the material of the second type of cathode is a transparent material, the first type of cathode corresponds to the first type of anode, and the second type of cathode corresponds to the second type of anode, comprises:

forming the first type of cathode and the second type of cathode on the light-emitting layer respectively by masks in two vacuum evaporation processes.

In the manufacturing method provided by the present disclosure, the step of forming the first type of cathode and the second type of cathode on the light-emitting layer, wherein the material of the first type of cathode is a non-transparent material, the material of the second type of cathode is a transparent material, the first type of cathode corresponds to the first type of anode, and the second type of cathode corresponds to the second type of anode, comprises:

forming the first type of cathode and the second type of cathode on the driving circuit layer simultaneously by a graytone mask or a halftone mask in a same vacuum evaporation process.

In a second aspect, the present disclosure provides a display panel using the above manufacturing method. The display panel includes a plurality of organic light-emitting diode (OLED) light-emitting units arranged in an array, the OLED light-emitting units comprise bottom emitting OLED units and top emitting OLED units, the bottom emitting OLED units comprise the first type of anode and the first type of cathode, and the top emitting OLED units comprise the second type of anode and the second type of cathode;

wherein light-emitting ways of adjacent OLED light-emitting units in a row direction or a column direction are different.

In the display panel provided by the present disclosure, the display panel comprises a first row of OLED light-emitting units comprising a plurality of first OLED light-emitting units, wherein light-emitting ways of adjacent first OLED light-emitting units are the same; and

a second row of OLED light-emitting units comprising a plurality of second OLED light-emitting units, wherein light-emitting ways of adjacent second OLED light-emitting units are the same;

wherein the light-emitting ways of the first OLED light-emitting units and the second OLED light-emitting units adjacent to each other are different in the column direction.

In the display panel provided by the present disclosure, the display panel comprises a first row of OLED light-emitting units comprising a plurality of first OLED light-emitting units, wherein light-emitting ways of adjacent first OLED light-emitting units are different; and

a second row of OLED light-emitting units comprising a plurality of second OLED light-emitting units, wherein light-emitting ways of adjacent second OLED light-emitting units are different;

wherein the light-emitting ways of the first OLED light-emitting units and the second OLED light-emitting units adjacent to each other are different in the column direction.

In the display panel provided by the present disclosure, the display panel comprises a first column of OLED light-emitting units comprising a plurality of third OLED light-emitting units, wherein light-emitting ways of adjacent third OLED light-emitting units are the same; and

a second column of OLED light-emitting units comprising a plurality of fourth OLED light-emitting units, wherein light-emitting ways of adjacent fourth OLED light-emitting units are the same;

wherein the light-emitting ways of the third OLED light-emitting units and the fourth OLED light-emitting units adjacent to each other are different in the row direction.

In a third aspect, an embodiment of the present disclosure provides a manufacturing method of a display device including the above display panel. The manufacturing method of the display device comprises following steps:

providing the substrate and forming the driving circuit layer on the substrate;

forming the first type of anode and the second type of anode on the driving circuit layer, wherein the material of the first type of anode is a transparent material, the material of the second type of anode is a non-transparent material, and the first type of anode is disposed adjacent to the second type of anode;

forming the light-emitting layer on the first type of anode and the second type of anode; and

forming the first type of cathode and the second type of cathode on the light-emitting layer, wherein the material of the first type of cathode is a non-transparent material, the material of the second type of cathode is a transparent material, the first type of cathode corresponds to the first type of anode, and the second type of cathode corresponds to the second type of anode.

In the manufacturing method of the display device provided by the present disclosure, the step of providing the substrate and forming the driving circuit layer on the substrate comprises:

forming a light shielding layer, a buffer layer, and an active layer on the substrate in a stack;

depositing a first metal layer on the active layer and patterning the first metal layer to form a gate electrode;

patterning to form a dielectric layer on the gate electrode, wherein the dielectric layer is provided with through-holes on the active layer; and

patterning to form a source electrode and a drain electrode on the through-holes.

In the manufacturing method of the display device provided by the present disclosure, the step of forming the first type of anode and the second type of anode on the driving circuit layer, wherein the material of the first type of anode is a transparent material, the material of the second type of anode is a non-transparent material, and the first type of anode is disposed adjacent to the second type of anode, comprises:

forming the first type of anode and the second type of anode on the driving circuit layer respectively by masks in two vacuum evaporation processes.

In the manufacturing method of the display device provided by the present disclosure, the step of forming the first type of anode and the second type of anode on the driving circuit layer, wherein the material of the first type of anode is a transparent material, the material of the second type of anode is a non-transparent material, and the first type of anode is disposed adjacent to the second type of anode, comprises:

forming the first type of anode and the second type of anode on the driving circuit layer simultaneously by a graytone mask or a halftone mask in a same vacuum evaporation process.

In the manufacturing method of the display device provided by the present disclosure, the step of forming the first type of cathode and the second type of cathode on the light-emitting layer, wherein the material of the first type of cathode is a non-transparent material, the material of the second type of cathode is a transparent material, the first type of cathode corresponds to the first type of anode, and the second type of cathode corresponds to the second type of anode, comprises:

forming the first type of cathode and the second type of cathode on the light-emitting layer respectively by masks in two vacuum evaporation processes.

In the manufacturing method of the display device provided by the present disclosure, the step of forming the first type of cathode and the second type of cathode on the light-emitting layer, wherein the material of the first type of cathode is a non-transparent material, the material of the second type of cathode is a transparent material, the first type of cathode corresponds to the first type of anode, and the second type of cathode corresponds to the second type of anode, comprises:

forming the first type of cathode and the second type of cathode on the driving circuit layer simultaneously by a graytone mask or a halftone mask in a same vacuum evaporation process.

In a fourth aspect, an embodiment of the present disclosure provides a display device which is manufactured using the above manufacturing method of the display device. The display panel includes a plurality of OLED light-emitting units arranged in an array, the OLED light-emitting units comprise bottom emitting OLED units and top emitting OLED units, the bottom emitting OLED units comprise the first type of anode and the first type of cathode, and the top emitting OLED units comprise the second type of anode and the second type of cathode;

wherein the light-emitting ways of the adjacent OLED light-emitting units in the row direction or the column direction are different.

In the display device provided by the present disclosure, the display panel comprises a first row of OLED light-emitting units comprising a plurality of first OLED light-emitting units, wherein light-emitting ways of adjacent first OLED light-emitting units are the same; and

a second row of OLED light-emitting units comprising a plurality of second OLED light-emitting units, wherein light-emitting ways of adjacent second OLED light-emitting units are the same;

wherein the light-emitting ways of the first OLED light-emitting units and the second OLED light-emitting units adjacent to each other are different in the column direction.

In the display device provided by the present disclosure, the display panel comprises a first row of OLED light-emitting units comprising a plurality of first OLED light-emitting units, wherein light-emitting ways of adjacent first OLED light-emitting units are different; and

a second row of OLED light-emitting units comprising a plurality of second OLED light-emitting units, wherein light-emitting ways of adjacent second OLED light-emitting units are different;

wherein the light-emitting ways of the first OLED light-emitting units and the second OLED light-emitting units adjacent to each other are different in the column direction.

In the display device provided by the present disclosure, the display panel comprises a first column of OLED light-emitting units comprising a plurality of third OLED light-emitting units, wherein light-emitting ways of adjacent third OLED light-emitting units are the same; and

a second column of OLED light-emitting units comprising a plurality of fourth OLED light-emitting units, wherein light-emitting ways of adjacent fourth OLED light-emitting units are the same;

wherein the light-emitting ways of the third OLED light-emitting units and the fourth OLED light-emitting units adjacent to each other are different in the row direction.

Beneficial effect: the present disclosure provides a display panel and a manufacturing method thereof. The method includes forming a driving circuit on a substrate, forming a first type of anode and a second type of anode on the driving circuit, forming a light-emitting layer on the first type of anode and the second type of anode, and forming a first type of cathode and a second type of cathode on the light-emitting layer. The first type of anode has light transmittance, the second type of anode has reflectivity, the first type of cathode has reflectivity, and the second type of cathode has light transmittance. The display panel manufactured by the method includes bottom emitting OLED units and top emitting OLED units. The bottom emitting OLED units include the first type of anode and the first type of cathode, and the top emitting OLED units include the second type of anode and the second type of cathode. Through disposing the top emitting OLED units and the bottom emitting OLED units on a same panel, dual-sided displaying of the display panel can be realized, processing costs can be reduced, and a thickness of the display panel can be reduced.

### DESCRIPTION OF DRAWINGS

The following detailed description of specific embodiments of the present disclosure will make the technical solutions and other beneficial effects of the present disclosure obvious with reference to the accompanying drawings.

FIG. 1 is a flowchart of a manufacturing method of a display panel according to an embodiment of the present disclosure.

FIG. 2 is a flowchart of a manufacturing method of a driving circuit according to an embodiment of the present disclosure.

FIGS. 3 to 9 are schematic structural diagrams of the display panel during the manufacturing method according to an embodiment of the present disclosure.

FIG. 10 is a schematic planar diagram of a dual-sided AMOLED display device according to an embodiment of the present disclosure.

FIG. 11 is a schematic diagram of a first arrangement of top emitting OLED units and bottom emitting OLED units in the display panel.

FIG. 12 is a schematic cross-sectional diagram of the first arrangement in FIG. 11.

FIG. 13 is a schematic diagram of a second arrangement of top emitting OLED units and bottom emitting OLED units in the display panel.

FIG. 14 is a schematic diagram of a third arrangement of top emitting OLED units and bottom emitting OLED units in the display panel.

### DETAILED DESCRIPTION OF PREFERRED EMBODIMENTS

The technical solutions in the embodiments of the present disclosure will be clearly and completely described below with reference to the drawings in the embodiments of the present disclosure. Obviously, the described embodiments are only a part of the embodiments of the present disclosure, but not all the embodiments. Based on the embodiments in the present disclosure, all other embodiments obtained by those skilled in the art without creative efforts are within the scope of the present disclosure.

In the description of the present disclosure, it should be understood that terms such as “center”, “longitudinal”, “lateral”, “length”, “width”, “thickness”, “upper”, “lower”, “front”, “rear”, “left”, “right”, “vertical”, “horizontal”, “top”, “bottom”, “inside”, “outside”, “clockwise”, “counter-clockwise”, as well as derivative thereof should be construed to refer to the orientation as described or as shown in the drawings under discussion. These relative terms are for convenience of description, do not require that the present disclosure be constructed or operated in a particular orientation, and shall not be construed as causing limitations to the present disclosure. In addition, terms such as “first” and “second” are used herein for purposes of description and are not intended to indicate or imply relative importance or implicitly indicating the number of technical features indicated. Thus, features limited by “first” and “second” are intended to indicate or imply including one or more than one these features. In the description of the present disclosure, “a plurality of” relates to two or more than two, unless otherwise specified.

In the description of the present disclosure, it should be noted that unless there are express rules and limitations, the terms such as “mount,” “connect,” and “bond” should be comprehended in broad sense. For example, it can mean a permanent connection, a detachable connection, or an integrated connection; it can mean a mechanical connection, an electrical connection, or can communicate with each other; it can mean a direct connection, an indirect connection by an intermediary, or an inner communication or an inter-reaction between two elements. A person skilled in the art should understand the specific meanings in the present disclosure according to specific situations.

In the description of the present disclosure, unless specified or limited otherwise, it should be noted that, a structure in which a first feature is “on” or “beneath” a second feature may include an embodiment in which the first feature directly contacts the second feature and may also include an embodiment in which an additional feature is formed between the first feature and the second feature so that the first feature does not directly contact the second feature. Furthermore, a first feature “on,” “above,” or “on top of” a second feature may include an embodiment in which the first feature is right “on,” “above,” or “on top of” the second feature and may also include an embodiment in which the first feature is not right “on,” “above,” or “on top of” the second feature, or just means that the first feature has a sea level elevation greater than the sea level elevation of the second feature. While first feature “beneath,” “below,” or “on bottom of” a second feature may include an embodiment in which the first feature is right “beneath,” “below,” or “on bottom of” the second feature and may also include an embodiment in which the first feature is not right “beneath,” “below,” or “on bottom of” the second feature, or just means that the first feature has a sea level elevation less than the sea level elevation of the second feature.

The following description provides many different embodiments or examples for implementing different structures of the present disclosure. In order to simplify the present disclosure, the components and settings of a specific example are described below. Of course, they are merely examples and are not intended to limit the present disclosure. In addition, the present disclosure may repeat reference numerals and/or reference letters in different examples, which are for the purpose of simplicity and clarity, and do not indicate the relationship between the various embodiments and/or arrangements discussed. In addition, the present disclosure provides examples of various specific processes and materials, but one of ordinary skill in the art will recognize the use of other processes and/or the use of other materials.

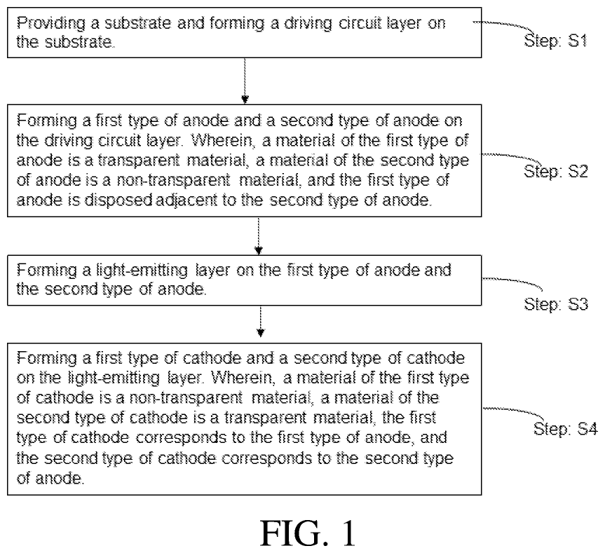

As shown in FIG. 1, an embodiment of the present disclosure provides a manufacturing method of a display panel, which can effectively relieve problems of manufacturing costs being too high and display devices being not light and thin enough existing in dual-sided display panels in current technology. The manufacturing method includes following steps.

Step S1: providing a substrate and forming a driving circuit layer on the substrate.

Step S2: forming a first type of anode and a second type of anode on the driving circuit layer. Wherein, a material of the first type of anode is a transparent material, a material of the second type of anode is a non-transparent material, and the first type of anode is disposed adjacent to the second type of anode.

Step S3: forming a light-emitting layer on the first type of anode and the second type of anode.

Step S4: forming a first type of cathode and a second type of cathode on the light-emitting layer. Wherein, a material of the first type of cathode is a non-transparent material, a material of the second type of cathode is a transparent material, the first type of cathode corresponds to the first type of anode, and the second type of cathode corresponds to the second type of anode.

Combing with FIGS. 3 to 9 for supplementary explanation of the manufacturing method of the display panel provided by the present disclosure, the display panel includes a substrate 100, a driving circuit 200, and a pixel definition layer 300. The driving circuit layer 200 includes a light shielding layer 210, a buffer layer 220, an active layer 230, a gate insulating layer 250, an interlayer dielectric layer 260, source and drain electrodes 270, and a passivation protective layer 280. The pixel definition layer 300 includes an anode 310, a light-emitting layer 320, and a cathode 310.

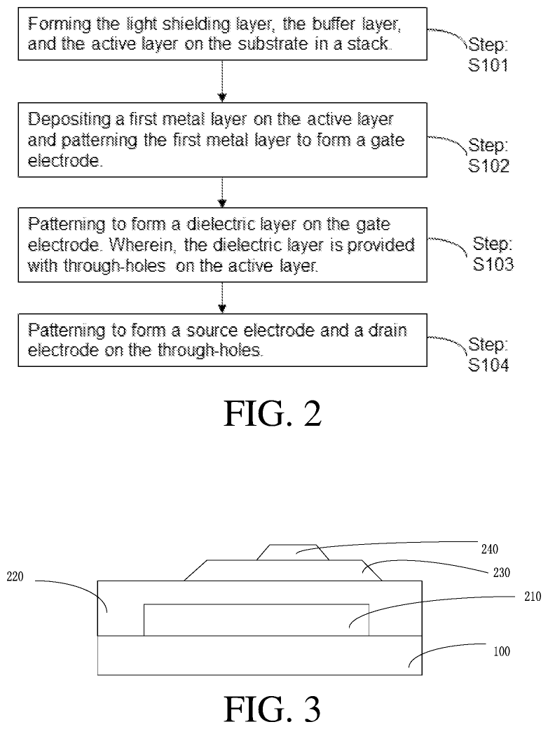

Specifically, the step 1 is illustrated with reference to FIG. 2. The step S1: providing the substrate and forming the driving circuit layer on the substrate includes following steps.

Step S101: forming the light shielding layer, the buffer layer, and the active layer on the substrate in a stack.

Step S102: depositing a first metal layer on the active layer and patterning the first metal layer to form a gate electrode.

Step S103: patterning to form a dielectric layer on the gate electrode. Wherein, the dielectric layer is provided with through-holes on the active layer.

Step S104: patterning to form a source electrode and a drain electrode on the through-holes.

Combined with FIG. 3, in the step S101, the light shielding layer 210 is a metal material which is metal copper or molybdenum. The light shielding layer 210 is deposited on the substrate by metal sputtering, and a diffusion barrier layer and an etching barrier layer are formed on the light shielding layer 210 at the same time. A material of the diffusion barrier layer is one of molybdenum oxide, metal molybdenum, or thallium. A material of the etching barrier layer is one of indium tin oxide (ITO) or indium gallium oxide (IGZO). The etching barrier layer is formed on the diffusion barrier layer by physical vapor sputtering, and the diffusion barrier layer and the etching barrier layer form patterns by photolithography. Photolithography for the diffusion barrier layer uses hydrogen peroxide, and photolithography for the etching barrier layer uses an oxalic acid solution. The buffer layer is deposited on the etching barrier layer by chemical vapor deposition, and a material of the buffer layer is one or more of silicon, silicon oxide, and silicon nitride. The active layer is sputtered on the buffer layer by physical vapor deposition, and the active layer is one of indium tin oxide or indium gallium oxide, and the active layer is formed using an oxalic acid solution to pattern in a photolithography process. The gate insulating layer is deposited on the active layer by chemical vapor deposition, and a material of the gate insulating layer is one or more of silicon, silicon oxide, and silicon nitride.

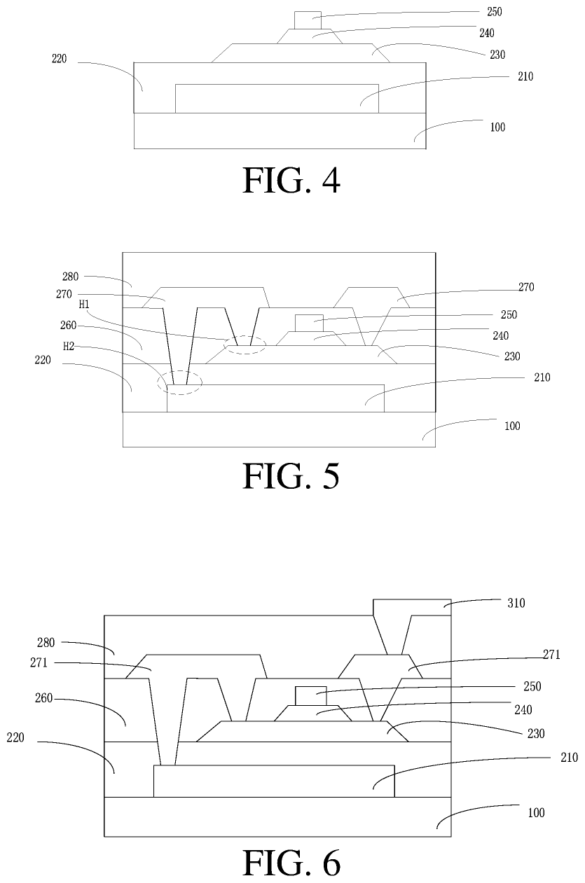

As shown in FIG. 4, in the step S102, the first metal layer is deposited on the gate insulating layer 240 by chemical vapor deposition, and the first metal layer is patterned by photolithography to form the gate electrode 250. In some embodiments, the material of the active layer is indium gallium oxide (IGZO), and after the gate electrode 250 is formed after peeling a photoresist for the first metal layer, the active layer is doped by a plasma treatment process.

As shown in FIG. 5, in the step S103, the dielectric layer 260 is formed and patterned on the gate electrode by chemical vapor deposition. The dielectric layer is provided with a first through-hole H1 on the active layer and the first through-hole H1 penetrates through the interlayer dielectric layer and forms on the active layer. A second through-hole H2 is formed on the etching barrier layer and penetrates through the interlayer dielectric layer 260 and the buffer layer 220. Meanwhile, the etching barrier layer is doped by a plasma treatment process to conductorization.

In the step S104, as shown in FIG. 5, a second metal layer 170 is deposited on the first through-hole and the second through-hole by chemical vapor deposition, a material of the second metal layer 170 is one of copper or molybdenum, and the second metal layer is patterned to form the source electrode and the drain electrode. A passivation layer 280 is deposited on the source electrode and the drain electrode.

Combined with FIG. 6, in the step S2: forming the anode 310 on the driving circuit layer 200. The anode includes the first type of anode and the second type of anode. The material of the first type of anode is a transparent material and is indium tin oxide in general, the material of the second type of anode is a non-transparent material and is one of metal silver or magnesium in general, and the first type of anode is disposed adjacent to the second type of anode. In some embodiments, the first type of anode and the second type of anode are formed on the driving circuit layer respectively by masks in two vacuum evaporation processes. In some embodiments, the first type of anode and the second type of anode are formed on the driving circuit layer simultaneously by a graytone mask or a halftone mask in a same vacuum evaporation process.

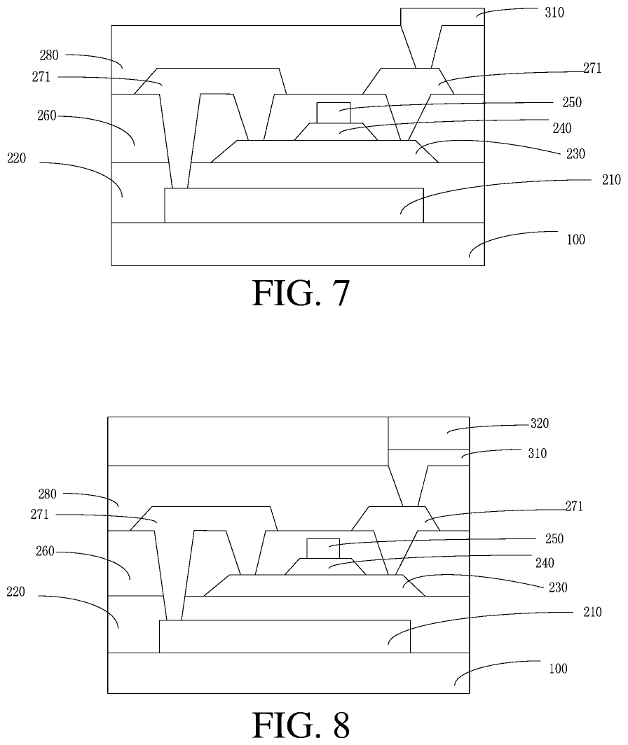

Combined with FIG. 7, in the step S3, the light-emitting layer 320 is formed on the first type of anode and the second type of anode, and the light-emitting layer 320 includes a hole injection layer (HIL), a hole transport layer (HTL), and an organic light-emitting layer (EML). The hole injection layer (HIL) and the hole transport layer (HTL) are formed on the anode 310 in sequence by inkjet printing, and the organic light-emitting layer (EML) is manufactured on the hole transport layer (HTL) by printing red sub-pixels, blue sub-pixels, and green sub-pixels in sequence.

Combined with FIG. 8, in the step S4: forming the cathode 330 on the light-emitting layer. The cathode includes the first type of cathode and the second type of cathode. The material of the first type of cathode is a non-transparent material and is one of metal silver or magnesium in general, the material of the second type of cathode is a transparent material and is indium tin oxide in general, the first type of cathode corresponds to the first type of anode, and the second type of cathode corresponds to the second type of anode. In some embodiments, the first type of cathode and the second type of cathode are formed on the light-emitting layer respectively by masks in two vacuum evaporation processes. In some embodiments, the first type of cathode and the second type of cathode are formed on the light-emitting layer simultaneously by a graytone mask or a halftone mask in a same vacuum evaporation process.

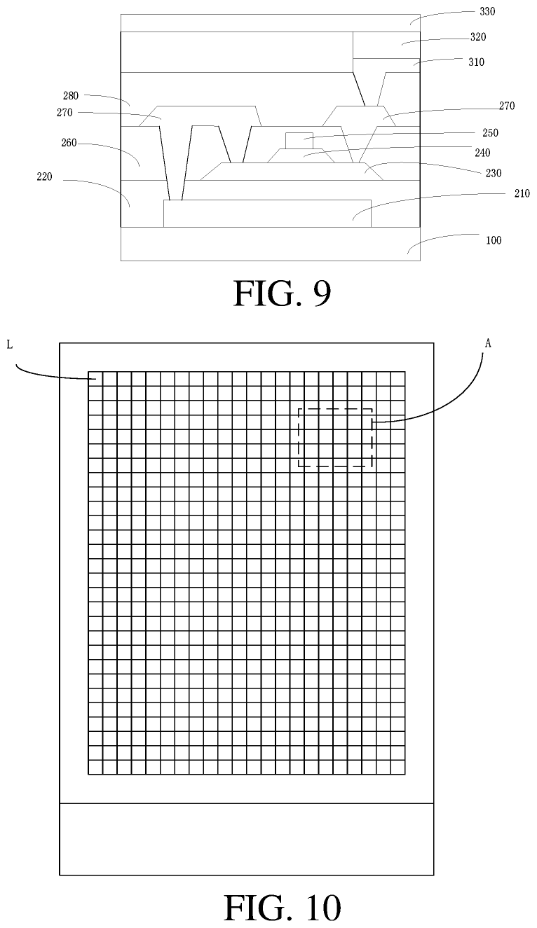

In order to further elaborate on the technical means adopted by the present disclosure and effects thereof, the following will be described in detail with reference to the preferred embodiments of the present disclosure and the accompanying drawings. Referring to FIGS. 9 to 14, the present disclosure provides a display panel manufactured by the above manufacturing method. The display panel includes the substrate 100 and the driving circuit layer 200 disposed on the substrate 100. The driving circuit layer 200 includes the light shielding layer 210, the buffer layer 220, the active layer 230, the gate insulating layer 250, the interlayer dielectric layer 260, the source and drain electrodes 270, and the passivation protective layer 280. The pixel definition layer is disposed on the driving circuit, and the pixel definition layer includes the anode 310, the light-emitting functional layer 320, and the cathode 330. The anode 310 includes the first type of anode and the second type of anode. The material of the first type of anode is a transparent material, the material of the second type of anode is a non-transparent material, and the first type of anode is disposed adjacent to the second type of anode. The cathode 330 includes the first type of cathode and the second type of cathode. The material of the first type of cathode is a non-transparent material, the material of the second type of cathode is a transparent material, the first type of cathode corresponds to the first type of anode, and the second type of cathode corresponds to the second type of anode.

In some embodiments, as shown in FIG. 10, in a display area of the display panel, the display panel includes a plurality of OLED light-emitting units L arranged in an array. The OLED light-emitting units comprise bottom emitting OLED units L1 and top emitting OLED units L2, the bottom emitting OLED units L1 comprise the first type of anode and the first type of cathode, and the top emitting OLED units L2 comprise the second type of anode and the second type of cathode. Wherein, light-emitting ways of adjacent OLED light-emitting units L in a row direction or a column direction are different. Therefore, through designing an image algorithm controlled by one single IC, the dual-sided display can be realized by only one display panel and one control IC, images seen in front or back of the display panel by an observer having no problems of left and right mirror images and direction distortion can be ensured, costs are low, and display effect is good.

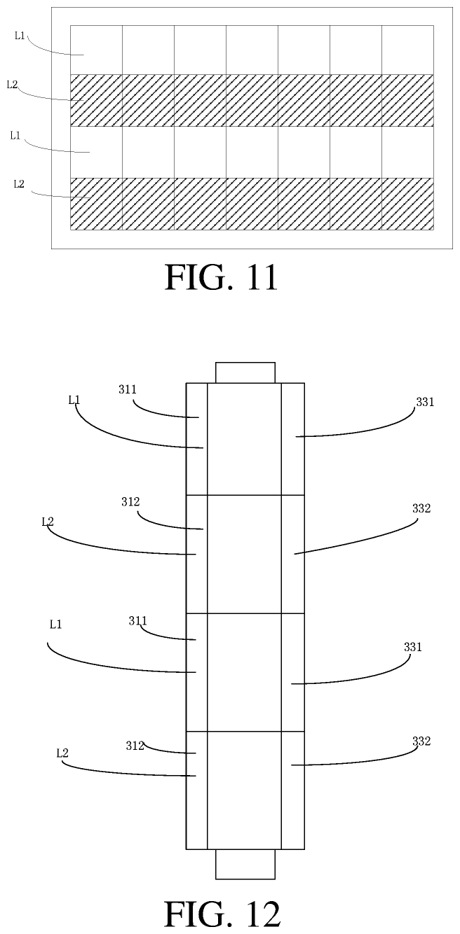

In some embodiments, one area A in the display area of the display panel of FIG. 10 is selected for partial enlargement to obtain FIG. 11, which is a schematic diagram of a first arrangement of the top emitting OLED units and the bottom emitting OLED units in the display panel. The display panel comprises a first row of OLED light-emitting units including a plurality of first OLED light-emitting units, wherein light-emitting ways of adjacent first OLED light-emitting units are the same.

The display panel comprises a second row of OLED light-emitting units including a plurality of second OLED light-emitting units, wherein light-emitting ways of adjacent second OLED light-emitting units are the same.

Wherein, the light-emitting ways of the first OLED light-emitting units and the second OLED light-emitting units adjacent to each other are different in the column direction.

In some embodiments, as shown in FIG. 11, the first OLED light-emitting units are bottom emitting OLED units L1, and the second OLED light-emitting units are top emitting OLED units L2.

In some embodiments, the first OLED light-emitting units are top emitting OLED units L2, and the second OLED light-emitting units are top emitting OLED units L2 and bottom emitting OLED units L1.

In some embodiments, since OLEDs are arranged alternatingly in a vertical direction and not arranged alternatingly in a horizontal direction, the plurality of top emitting OLED units L2 and the plurality of bottom emitting OLED units L1 constitute an OLED unit array together. Wherein, each odd row has the bottom emitting OLED units L1, and each even row has the top emitting OLED units L2. At this time, when the image algorithm controlled by the corresponding single IC is displayed, drive signals of two adjacent rows of OLED units are the same. For example, assume the formed OLED unit array is an array of m columns and 2n rows, wherein, m and n are all positive integers. Image signals received by 1st, 2nd, 3rd, . . . , and nth bottom emitting OLED units L1 from top to bottom of a first row are respectively S11, S12, S13, . . . , and S1n, and image signals received by 2nd, 4th, 6th, . . . , and 2nth top emitting OLED units L2 from top to bottom of a first row are respectively S11, S12, S13, . . . , and S1n. By the same signals in two adjacent rows, the present disclosure only needs one display panel and one control IC to realize the dual-sided display and ensure it to have the same observation.

FIG. 12 is a schematic cross-sectional diagram of the first arrangement in FIG. 11. The anode 310 includes the first type of anode 311 and the second type of anode 312. The material of the first type of anode 311 is a transparent material and is indium tin oxide in general, the material of the second type of anode 312 is a non-transparent material and is one of metal silver or magnesium in general, and the first type of anode is disposed adjacent to the second type of anode. The first type of anode 311 and the second type of anode 312 may be formed respectively by masks in the two vacuum evaporation processes, or may be formed simultaneously by the graytone mask or the halftone mask in the same vacuum evaporation process. For example, first, a thin layer of a first type of anode film having light transmittance can be evaporated through a mask having a pixel pattern, and then a thicker layer of a second type of anode film having reflectivity to prevent light from transmitting is evaporated on the first type of anode film corresponding to an area to form the top emitting OLED units L2 through another mask having a pixel pattern. Therefore, the first type of anode film and the second type of anode film corresponding to the top emitting OLED units L2 constitute the second type of anode 312, and the first type of anode film corresponding to the bottom emitting OLED units L1 constitutes the first type of anode 311. The cathode 330 includes the first type of cathode 321 and the second type of cathode 322. The material of the first type of cathode 321 is a non-transparent material and is one of metal silver or magnesium in general, the material of the second type of cathode 322 is a transparent material and is indium tin oxide in general, the first type of cathode 321 corresponds to the first type of anode 311, and the second type of cathode corresponds to the second type of anode. The light-emitting functional layer is formed between the anode and the cathode, and the light-emitting functional layer includes the hole injection layer, the hole transport layer, the light-emitting layer, and the electron transport/injection layer disposed in sequence in a stack from bottom to top.

Since the top emitting OLED units L2 and the bottom emitting OLED units L1 emit light backward or toward the substrate of the display panel respectively, the bottom emitting OLED units L1 should be disposed in an area of the substrate 100 where light is not blocked, while the top emitting OLED units L2 may be disposed in the area where the light is not blocked or an area where the light is blocked. For example, the top emitting OLED units L2 may be disposed on TFT devices where the light is usually not allowed to transmit, thereby increasing a luminous area and improving pixel aperture ratio.

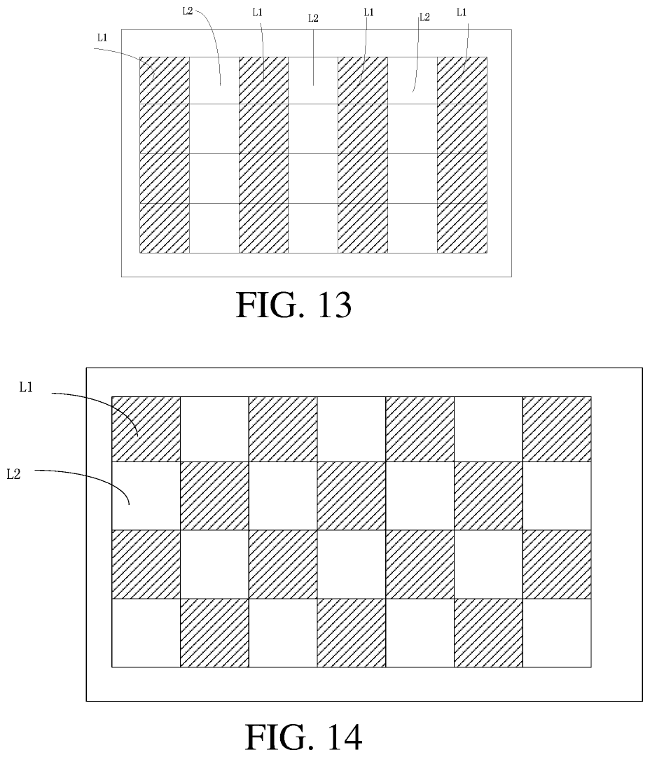

In some embodiments, one area A in the display area of the display panel of FIG. 10 is selected for partial enlargement to obtain FIG. 13, which is a schematic diagram of a second arrangement of the top emitting OLED units and the bottom emitting OLED units in the display panel. The display panel comprises a first row of OLED light-emitting units including a plurality of first OLED light-emitting units, wherein light-emitting ways of adjacent first OLED light-emitting units are different.

The display panel comprises a second row of OLED light-emitting units including a plurality of second OLED light-emitting units, wherein light-emitting ways of adjacent second OLED light-emitting units are different.

Wherein, the light-emitting ways of the first OLED light-emitting units and the second OLED light-emitting units adjacent to each other are different in the column direction.

In some embodiments, as shown in FIG. 13, the first OLED light-emitting units are bottom emitting OLED units L1, and the second OLED light-emitting units are top emitting OLED units L2.

In some embodiments, the first OLED light-emitting units are top emitting OLED units L2, and the second OLED light-emitting units are top emitting OLED units L2 and bottom emitting OLED units L1.

In some embodiments, since OLEDs are arranged alternatingly in the horizontal direction and not arranged alternatingly in the vertical direction, the plurality of top emitting OLED units L2 and the plurality of bottom emitting OLED units L1 constitute an OLED unit array together. Wherein, each odd column has the bottom emitting OLED units L1, and each even column has the top emitting OLED units L2. At this time, when the image algorithm controlled by the corresponding single IC is displayed, drive signals of two adjacent columns of OLED units are the same. For example, assume the formed OLED unit array is an array of m columns and 2n rows, wherein, m and n are all positive integers. A first row is taken as an example, image signals received by 1st, 2nd, 3rd, . . . , and nth bottom emitting OLED units L1 from left to right of the first row are respectively S11, S12, S13, . . . , and S1n, and image signals received by 2nd, 4th, 6th, . . . , and 2nth top emitting OLED units L2 from left to right of the first row are respectively S11, S12, S13, . . . , and S1n. By the same signals in two adjacent columns, the present disclosure only needs one display panel and one control IC, which can drive two rows at the same time, to realize the dual-sided display and ensure it to have the same observation.

In some embodiments, one area A in the display area of the display panel of FIG. 10 is selected for partial enlargement to obtain FIG. 14, which is a schematic diagram of a third arrangement of the top emitting OLED units and the bottom emitting OLED units in the display panel. The display panel comprises a first column of OLED light-emitting units comprising a plurality of third OLED light-emitting units, wherein light-emitting ways of adjacent third OLED light-emitting units are the same. The display panel comprises a second column of OLED light-emitting units comprising a plurality of fourth OLED light-emitting units, wherein light-emitting ways of adjacent fourth OLED light-emitting units are the same. Wherein, the light-emitting ways of the third OLED light-emitting units and the fourth OLED light-emitting units adjacent to each other are different in the row direction.

In some embodiments, as shown in FIG. 14, the third OLED light-emitting units are bottom emitting OLED units L1, and the fourth OLED light-emitting units are top emitting OLED units L2.

In some embodiments, the third OLED light-emitting units are top emitting OLED units L2, and the fourth OLED light-emitting units are top emitting OLED units L2 and bottom emitting OLED units L1.

In some embodiments, as shown in FIG. 14, in the OLED array layer 200, the top emitting OLED units L2 and the bottom emitting OLED units L1 are arranged alternatingly in the horizontal direction and the vertical direction, the adjacent top emitting OLED units L2 and the bottom emitting OLED units L1 constitute an OLED unit array together, and drive signals of the adjacent bottom emitting OLED units L1 and top emitting OLED units L2 are the same. For example, assume the formed OLED unit array is an array of m columns and n rows, wherein, m and n are all positive integers. A first row and a second row are taken as examples, image signals received by 1st, 2nd, 3rd, . . . , and nth top emitting OLED units L2 from left to right of the first row are respectively S11, S12, S13, . . . , and S1n, and image signals received by 1st, 2nd, 3rd, . . . , and mth top emitting OLED units L2 from left to right of the second row are respectively S11, S12, S13, . . . , and S1n. Meanwhile, in the present disclosure, gate electrode lines of the display panel are driven alternatingly in the column direction, which ensures drive signals of the gate electrode lines in odd columns and even columns are the same, and thus, the dual-sided display can be realized by only one display panel and one control IC, and images seen in front or back of the display panel by an observer having no problems of left and right mirror images and direction distortion can be ensured.

The present disclosure provides a manufacturing method of a display panel and the display panel manufactured by the method. The method includes forming a driving circuit on a substrate, forming a first type of anode and a second type of anode on the driving circuit, forming a light-emitting layer on the first type of anode and the second type of anode, and forming a first type of cathode and a second type of cathode on the light-emitting layer. The first type of anode has light transmittance, the second type of anode has reflectivity, the first type of cathode has reflectivity, and the second type of cathode has light transmittance. The display panel manufactured by the method includes bottom emitting OLED units and top emitting OLED units. The bottom emitting OLED units include the first type of anode and the first type of cathode, and the top emitting OLED units include the second type of anode and the second type of cathode. Through disposing the top emitting OLED units and the bottom emitting OLED units on a same panel, dual-sided displaying of the display panel can be realized, processing costs can be reduced, and a thickness of the display panel can be reduced.

The following description provides many different embodiments or examples for implementing different structures of the present disclosure. In order to simplify the present disclosure, the components and settings of a specific example are described below. Of course, they are merely examples and are not intended to limit the present disclosure. In addition, the present disclosure may repeat reference numerals and/or reference letters in different examples, which are for the purpose of simplicity and clarity, and do not indicate the relationship between the various embodiments and/or arrangements discussed. In addition, the present disclosure provides examples of various specific processes and materials, but one of ordinary skill in the art will recognize the use of other processes and/or the use of other materials.

In the above embodiments, the description of each embodiment has its own emphasis. For the parts that are not described in detail in an embodiment, refer to the detailed description of other embodiments above.

The display panel and the manufacturing method thereof provided by the present disclosure are described in detail above. The specific examples are applied in the description to explain the principle and implementation of the disclosure. The description of the above embodiments is only for helping to understand the technical solution of the present disclosure and its core ideas, and it is understood that many changes and modifications to the described embodiment can be carried out without departing from the scope and the spirit of the disclosure that is intended to be limited only by the appended claims.

What is claimed is:

1. A manufacturing method of a display panel, comprising following steps:
providing a substrate and forming a driving circuit layer on the substrate;
forming a first type of anode and a second type of anode on the driving circuit layer, wherein a material of the first type of anode is a transparent material, a material of the second type of anode is a non-transparent material, and the first type of anode is disposed adjacent to the second type of anode;
forming a light-emitting layer on the first type of anode and the second type of anode; and
forming a first type of cathode and a second type of cathode on the light-emitting layer, wherein a material of the first type of cathode is a non-transparent material, a material of the second type of cathode is a transparent material, the first type of cathode corresponds to the first type of anode, and the second type of cathode corresponds to the second type of anode.

2. The manufacturing method according to claim 1, wherein the step of providing the substrate and forming the driving circuit layer on the substrate comprises:
forming a light shielding layer, a buffer layer, and an active layer on the substrate in a stack;
depositing a first metal layer on the active layer and patterning the first metal layer to form a gate electrode;
patterning to form a dielectric layer on the gate electrode, wherein the dielectric layer is provided with through-holes on the active layer; and
patterning to form a source electrode and a drain electrode on the through-holes.

3. The manufacturing method according to claim 1, wherein the step of forming the first type of anode and the second type of anode on the driving circuit layer, wherein the material of the first type of anode is the transparent material, the material of the second type of anode is the non-transparent material, and the first type of anode is disposed adjacent to the second type of anode, comprises:
forming the first type of anode and the second type of anode on the driving circuit layer respectively by masks in two vacuum evaporation processes.

4. The manufacturing method according to claim 1, wherein the step of forming the first type of anode and the second type of anode on the driving circuit layer, wherein the material of the first type of anode is the transparent material, the material of the second type of anode is the non-transparent material, and the first type of anode is disposed adjacent to the second type of anode, comprises:
forming the first type of anode and the second type of anode on the driving circuit layer simultaneously by a graytone mask or a halftone mask in a same vacuum evaporation process.

5. The manufacturing method according to claim 1, wherein the step of forming the first type of cathode and the second type of cathode on the light-emitting layer, wherein the material of the first type of cathode is the non-transparent material, the material of the second type of cathode is the transparent material, the first type of cathode corresponds to the first type of anode, and the second type of cathode corresponds to the second type of anode, comprises:
forming the first type of cathode and the second type of cathode on the light-emitting layer respectively by masks in two vacuum evaporation processes.

6. The manufacturing method according to claim 1, wherein the step of forming the first type of cathode and the second type of cathode on the light-emitting layer, wherein the material of the first type of cathode is the non-transparent material, the material of the second type of cathode is the transparent material, the first type of cathode corresponds to the first type of anode, and the second type of cathode corresponds to the second type of anode, comprises:
forming the first type of cathode and the second type of cathode on the driving circuit layer simultaneously by a graytone mask or a halftone mask in a same vacuum evaporation process.

7. A display panel using the manufacturing method according to claim 1 and comprising a plurality of organic light-emitting diode (OLED) light-emitting units arranged in an array, wherein the OLED light-emitting units comprise bottom emitting OLED units and top emitting OLED units, the bottom emitting OLED units comprise the first type of anode and the first type of cathode, and the top emitting OLED units comprise the second type of anode and the second type of cathode;
wherein light-emitting ways of adjacent OLED light-emitting units in a row direction or a column direction are different.

8. The display panel according to claim 7, comprising
a first row of the OLED light-emitting units comprising a plurality of first OLED light-emitting units, wherein light-emitting ways of adjacent first OLED light-emitting units are same; and
a second row of the OLED light-emitting units comprising a plurality of second OLED light-emitting units, wherein light-emitting ways of adjacent second OLED light-emitting units are same;
wherein the light-emitting ways of the first OLED light-emitting units and the second OLED light-emitting units adjacent to each other are different in the column direction.

9. The display panel according to claim 7, comprising
a first row of the OLED light-emitting units comprising a plurality of first OLED light-emitting units, wherein light-emitting ways of adjacent first OLED light-emitting units are different; and
a second row of the OLED light-emitting units comprising a plurality of second OLED light-emitting units, wherein light-emitting ways of adjacent second OLED light-emitting units are different;
wherein the light-emitting ways of the first OLED light-emitting units and the second OLED light-emitting units adjacent to each other are different in the column direction.

10. The display panel according to claim 7, comprising
a first column of the OLED light-emitting units comprising a plurality of third OLED light-emitting units, wherein light-emitting ways of adjacent third OLED light-emitting units are same; and
a second column of the OLED light-emitting units comprising a plurality of fourth OLED light-emitting units, wherein light-emitting ways of adjacent fourth OLED light-emitting units are same;
wherein the light-emitting ways of the third OLED light-emitting units and the fourth OLED light-emitting units adjacent to each other are different in the row direction.

11. A manufacturing method of a display device comprising the display panel according to claim 7, comprising following steps:
providing the substrate and forming the driving circuit layer on the substrate;
forming the first type of anode and the second type of anode on the driving circuit layer, wherein the material of the first type of anode is the transparent material, the material of the second type of anode is the non-transparent material, and the first type of anode is disposed adjacent to the second type of anode;
forming the light-emitting layer on the first type of anode and the second type of anode; and
forming the first type of cathode and the second type of cathode on the light-emitting layer, wherein the material of the first type of cathode is the non-transparent material, the material of the second type of cathode is the transparent material, the first type of cathode corresponds to the first type of anode, and the second type of cathode corresponds to the second type of anode.

12. The manufacturing method according to claim 11, wherein the step of providing the substrate and forming the driving circuit layer on the substrate comprises:
forming a light shielding layer, a buffer layer, and an active layer on the substrate in a stack;
depositing a first metal layer on the active layer and patterning the first metal layer to form a gate electrode;
patterning to form a dielectric layer on the gate electrode, wherein the dielectric layer is provided with through-holes on the active layer; and
patterning to form a source electrode and a drain electrode on the through-holes.

13. The manufacturing method according to claim 11, wherein the step of forming the first type of anode and the second type of anode on the driving circuit layer, wherein the material of the first type of anode is the transparent material, the material of the second type of anode is the non-transparent material, and the first type of anode is disposed adjacent to the second type of anode, comprises:
forming the first type of anode and the second type of anode on the driving circuit layer respectively by masks in two vacuum evaporation processes.

14. The manufacturing method according to claim 11, wherein the step of forming the first type of anode and the second type of anode on the driving circuit layer, wherein the material of the first type of anode is the transparent material, the material of the second type of anode is the non-transparent material, and the first type of anode is disposed adjacent to the second type of anode, comprises:
forming the first type of anode and the second type of anode on the driving circuit layer simultaneously by a graytone mask or a halftone mask in a same vacuum evaporation process.

15. The manufacturing method according to claim 11, wherein the step of forming the first type of cathode and the second type of cathode on the light-emitting layer, wherein the material of the first type of cathode is the non-transparent material, the material of the second type of cathode is the transparent material, the first type of cathode corresponds to the first type of anode, and the second type of cathode corresponds to the second type of anode, comprises:
forming the first type of cathode and the second type of cathode on the light-emitting layer respectively by masks in two vacuum evaporation processes.

16. The manufacturing method according to claim 11, wherein the step of forming the first type of cathode and the second type of cathode on the light-emitting layer, wherein the material of the first type of cathode is the non-transparent material, the material of the second type of cathode is the transparent material, the first type of cathode corresponds to the first type of anode, and the second type of cathode corresponds to the second type of anode, comprises:
forming the first type of cathode and the second type of cathode on the driving circuit layer simultaneously by a graytone mask or a halftone mask in a same vacuum evaporation process.

17. A display device using the manufacturing method according to claim 11, wherein the display panel comprises the plurality of OLED light-emitting units arranged in the array, the OLED light-emitting units comprise the bottom emitting OLED units and the top emitting OLED units, the bottom emitting OLED units comprise the first type of anode and the first type of cathode, and the top emitting OLED units comprise the second type of anode and the second type of cathode;
wherein the light-emitting ways of the adjacent OLED light-emitting units in the row direction or the column direction are different.

18. The display device according to claim 17, wherein the display panel comprises:
a first row of the OLED light-emitting units comprising a plurality of first OLED light-emitting units, wherein light-emitting ways of adjacent first OLED light-emitting units are same; and
a second row of the OLED light-emitting units comprising a plurality of second OLED light-emitting units, wherein light-emitting ways of adjacent second OLED light-emitting units are same;
wherein the light-emitting ways of the first OLED light-emitting units and the second OLED light-emitting units adjacent to each other are different in the column direction.

19. The display device according to claim 17, wherein the display panel comprises:
a first row of the OLED light-emitting units comprising a plurality of first OLED light-emitting units, wherein light-emitting ways of adjacent first OLED light-emitting units are different; and
a second row of the OLED light-emitting units comprising a plurality of second OLED light-emitting units, wherein light-emitting ways of adjacent second OLED light-emitting units are different;
wherein the light-emitting ways of the first OLED light-emitting units and the second OLED light-emitting units adjacent to each other are different in the column direction.

20. The display device according to claim 17, wherein the display panel comprises
a first column of the OLED light-emitting units comprising a plurality of third OLED light-emitting units, wherein light-emitting ways of adjacent third OLED light-emitting units are same; and
a second column of the OLED light-emitting units comprising a plurality of fourth OLED light-emitting units, wherein light-emitting ways of adjacent fourth OLED light-emitting units are same;
wherein the light-emitting ways of the third OLED light-emitting units and the fourth OLED light-emitting units adjacent to each other are different in the row direction.
